(19) United States
(12) Patent Application Publication
(10) Pub. No.: US 2021/0150443 A1
(43) Pub. Date: May 20, 2021

(54) PARITY DETECTION AND RECOMMENDATION SYSTEM

(71) Applicant: SAP SE, Walldorf (DE)

(72) Inventors: Jenngang Shih, Sunnyvale, CA (US); Ritesh Chopra, San Jose, CA (US)

(21) Appl. No.: 16/688,039

(22) Filed: Nov. 19, 2019

(51) Int. Cl. G06Q 10/06; G06Q 10/10; G06N 5/04; G06N 20/00; G06F 30/27

(52) U.S. Cl. CPC G06Q 10/06395; G06Q 10/105; G06F 3/04847; G06N 20/00; G06F 30/27; G06N 5/04

(57) ABSTRACT

Provided is a system and method for detecting parity among a group of users and recommending changes to address the parity. In one example, the method may include generating parity values for a group of users, where each parity value comprises an indicator of inequity for a value of a respective user with respect to corresponding values of other users in the group, predicting at least one category of data that most greatly influences the parity values for the group of users based on one or more machine learning models, identifying a user that has a parity value below a predetermined threshold, and determining an action which will improve the parity value of the identified user based on the at least one predicted influential category, and outputting a recommendation which includes the action.

### BACKGROUND

Gender diversity (as well as other types of diversity) are workplace imperatives. For example, organizations that provide opportunities to men, women, people of all ethnicities and sexual orientations report increased performance, greater innovation, and improved customer satisfaction. While organizations are beginning to improve on the diversity of their workforce, other problems may still remain such as fairness in employee compensation among the different diversities, also referred to as pay equity. Many organizations do not have a pay equity review process even though concern for fairness, pressure from inventors, and increasing regulatory actions are rising. Further, when an organization senses unfairness in pay towards a particular group, it may be difficult for the organization to identify actionable information, beyond just simple compensation numbers. However, other influences may be driving the problem.

### BRIEF DESCRIPTION OF THE DRAWINGS

Features and advantages of the example embodiments, and the manner in which the same are accomplished, will become more readily apparent with reference to the following detailed description taken in conjunction with the accompanying drawings.

FIG. 1 is a diagram illustrating a computing environment for parity detection and recommendation in accordance with an example embodiment.

FIG. 2A is a diagram illustrating a process of grouping users based on contextual attributes in accordance with an example embodiment.

FIG. 2B is a diagram displaying evidence of possible parity issues among categories of job-related attributes of a group of users in accordance with an example embodiment.

FIG. 2C is a diagram displaying user values per category and a parity index associated with the user values in accordance with an example embodiment.

FIG. 3A is a diagram illustrating a user interface displaying parity information of an organization in accordance with an example embodiment.

FIG. 3B is a diagram illustrating a process for creating an explanation of pay disparity in accordance with an example embodiment.

FIGS. 4A-4D are diagrams illustrating a simulation interface for simulating a change in parity information based on user inputs in accordance with an example embodiment.

FIG. 5 is a diagram illustrating a method of detecting parity values and making a recommendation based thereon, in accordance with an example embodiment.

FIG. 6 is a diagram illustrating a computing system for use in the examples herein in accordance with an example embodiment.

Throughout the drawings and the detailed description, unless otherwise described, the same drawing reference numerals will be understood to refer to the same elements, features, and structures. The relative size and depiction of these elements may be exaggerated or adjusted for clarity, illustration, and/or convenience.

### DETAILED DESCRIPTION

In the following description, specific details are set forth in order to provide a thorough understanding of the various example embodiments. It should be appreciated that various modifications to the embodiments will be readily apparent to those skilled in the art, and the generic principles defined herein may be applied to other embodiments and applications without departing from the spirit and scope of the disclosure. Moreover, in the following description, numerous details are set forth for the purpose of explanation. However, one of ordinary skill in the art should understand that embodiments may be practiced without the use of these specific details. In other instances, well-known structures and processes are not shown or described in order not to obscure the description with unnecessary detail. Thus, the present disclosure is not intended to be limited to the embodiments shown but is to be accorded the widest scope consistent with the principles and features disclosed herein.

Pay inequity (e.g., gender pay inequity, etc.) refers to the wage gap between men and women in the work place. Put simply, pay inequity (breach of pay equity) occurs when two employees/workers performing the same job, at the same location, and having the same tenure and performance, receive different pay. Pay inequity often occurs between men and women working the same role/job. According to the Institute for Women's Policy and Research, in 2017, female employees made approximately 80 cents for every dollar earned by a male employee. The reasons for the gap can vary and can include social factors, discrimination, motherhood, and the like. Furthermore, pay inequity is prevalent in many geographical regions, companies of different sizes, and across different industries. Rectifying the gap is an expensive task that is often associated with numerous legal liabilities. Furthermore, in many cases pay inequity is unintentional. In some cases, companies are not even aware of the issue unless or until they conduct a review of their compensation company-wide.

The example embodiments provide a solution to automatically detect pay inequity, understand what and why this is happening, and to prescribe a solution or multiple solutions for how to solve the problem in consideration of costs and future employee retention. The system described herein can generate a pay equity index (PEI), also referred to herein as a parity value, which indicates a degree in parity in pay. For example, the system may generate individual PEIs for employees, and more general PEIs for an organization as a whole. The pay equity index may be data-driven and may be accompanied by compensation domain knowledge. Various job-related attributes of the employees may be considered when determining the PEI including experience, salary, gender, work function, reviews/ratings, and the like. Rather than compare compensation by itself, which may not tell the entire story, the pay equity index provides a way to normalize pay equality among different users in different areas of the company, different geographies, titles, job functions, and the like.

Furthermore, the system may apply machine learning techniques (e.g., regression analysis, etc.) which can predict what attributes influence the pay equity index among a group of users. Influences may include characteristics such as manager churn/turnover, maternity leave, low starting salary ratio, and the like. Based on the influences, the system can provide recommendations of actions to be taken to improve the pay equity across a group of users in consideration of cost, and possible employee departure.

In some of the examples herein, the pay equity/parity is discussed as parity between gender (female and male). However, parity is not just limited to gender and it should be appreciated that the example embodiments may be applied to other situations as well. For example, parity can come occur among different ethnicities, different generations, different ages, etc. In addition, parity may not just be based on compensation but can be applied to other types of benefits or rewards. Therefore, it should be appreciated that the examples herein can identify parity related to any measurable benefit, opportunity, reward, etc., that can be extended to a person/employee and not just compensation. Other measurables include a number of opportunities given, a number of benefits given, and the like.

For example, a result of the analysis may reveal the cause of pay parity may or may not be gender related. For example, the parity may be caused by other HR attributes used in the analysis, such as generation, ethnicity, and other employ activities including starting salary, manager stability, extended leave, etc. Furthermore, pay parity is one of many parities that could occur in the workplace, and also includes other elements such as opportunity, workload, other HR benefits, perks, etc. since the approach is generic, it can be applied to many of them, if not all them at once.

According to various embodiments, the newly described pay equity index normalizes compensation for employees in a same area/job of the company, when the employees have other similar criteria such as job type, job performance, tenure, geographical location, etc. The attributes can be customized to suit the need. In other words, the pay equity index provides a value which can be used to compare employees with each other based on different attributes such as job title, job function, category of the company, and the like. The pay equity index can be generated based on employees who have similar attributes such as location, tenure (time at the company), performance, etc. However, once generated, the pay equity index can be used to compare two employees from different job functions. In other words, the pay equity index provides a normalization value which can be used to compare all employees with each other, even employees who work in different areas of the company, locations, job titles, etc.

As a non-limiting example, Lisa and John may be grouped together based on contextual attributes. For example, Lisa and John may have a same job function, work at a same location, have the same tenure, and have the same performance scores. Yet, Lisa may be paid below the median salary in a first job category (e.g., Job Function), while John's pay is above the median in the category. However, instead of just comparing the salaries/compensation of Lisa and John based on the one job category, they may be compared across multiple different categories such as job title, business unit, job family, and the like. This allows for Lisa and John to be compared against different users in the different categories, where each of the categories are associated with Lisa and John.

Continuing with this example, assume that Lisa and John are compared across a total of three categories. In this example, if Lisa has a pay disparity in three of three categories analyzed, she may receive a pay equity index of 1.00. Here, the pay equity index may be three categories divided by three categories. Meanwhile, if John has a pay disparity in one of the three categories, he may receive a pay equity index of 0.33. Here, the pay equity index may be calculated by dividing one category by three categories. The system may identify the pay equity index for all users based on salaries across multiple different categories to generate the pay equity index. Furthermore, once generated, the pay index value can be compared company wide since it is a normalizing value. In other words, the pay index can identify pay disparity in a normalizing fashion.

It should also be appreciated that the pay equity index may be calculated in different ways. In one example, a partial pay equity index or partial index may be calculated for each category (i) that the employee can be grouped into based on the employee's salary with respect to the median and maximum salaries in that category. For example, the partial index (PEI′) for a category (i) may be determined by the equation below.

PEIᵢ=(Median Salaryᵢ−Employee_{Salaryi})/(Max Salaryᵢ−Min Salaryᵢ)

Meanwhile, the total PEI may be generated by performing this same partial index calculation for all categories and then summing the values together or taking an average of the values, etc. Furthermore, the total PEI may be converted into a pay equity score (PES) which can be more user friendly. For example, a pay equity index of 0.33 may be converted or otherwise flipped into a pay equity score of 67% (or simply 67) out of 100% possible (or just 100), as shown in the equation below.

Pay Equity Score=100−(PEI*100)

The pay equity index and the pay equity score described herein represent a degree of pay parity among employees. For example, a PEI of 0 (which corresponds to a pay equity score of 100%) refers to a perfect score or zero pay inequality. Likewise, a PEI of 1.00 (which corresponds to a pay equity score of 0%) refers to a maximum inequality of pay, or the worst case scenario. The system may identify which users are more impacted by the pay equity disparity using the pay equity index/score. Furthermore, an identification of the users, the pay equity scores, and suggested recommendations for fixing the issues may be output to a user interface where an administrator of the company (or some other user) can view the results and simulate changes.

Furthermore, different types of users may use the parity application described herein and may have different interests and purposes when using the software. For example, types of users may include employees, human resource users, admins, employer management, etc. These different users may look at different aspects to solve different problems. For example, a company president may be trying to repair corporate image, while a human resources user may be trying to solve employee retention issues. Furthermore, employees may use the application to feel good about their current compensation. The parity application provides a tool to achieve these different interests for different types of users.

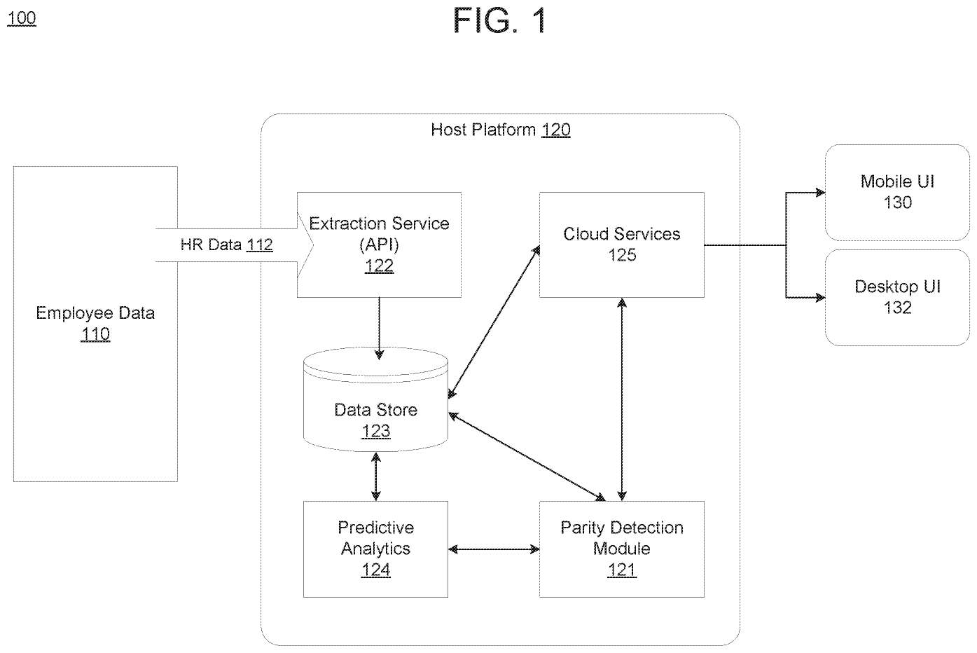

FIG. 1 illustrates a computing environment 100 for parity detection and recommendation in accordance with an example embodiment. Referring to FIG. 1, the computing environment 100 includes a data store 110 which includes employee data, a host platform 120, and a user device (not shown). In this example, the employee data 110 may include compensation data of employees within a company. The employees may also be referred to as users. The employee data 110 may include historical data related to pay equity and contextual attributes of the users within the company including current salary information, starting salary information, geographical locations of users, tenure information, performance evaluation information, previous experience, and the like.

The host platform 120 may include a central platform such as a server, a database, a cloud platform, or the like. The host platform 120 may host the parity detection and recommendation software described herein. For example, a parity detection module 121 may run on top of a database engine may execute or run the parity detection and recommendation software described in various embodiments herein. In this example, the host platform 120 may include an extraction service 122 which can retrieve or otherwise receive human resources data 112 from the employee database 110. Here, the extraction service 122 may include one or more application programming interfaces (APIs) for communicating with and identifying the necessary data from the customer data 110. The received human resources data 112 may be stored within a data store 123 of the host platform. Here, the data store 123 may include a relational database which stores the data in tabular format with columns and rows. However, the data store 123 is not limited to a relational database and may include any type of data store. The data store 123 may be part of or otherwise controlled by the parity detection module 121.

The parity detection module 121 may store and execute the procedural components (business rules) of the host platform 120 and may also include or otherwise control predictive analytics 124 which are accessible by the host platform 120. Furthermore, the parity detection module 121 may control access to the data store 123. The predictive analytics 124 can make predictions from the human resources data 112 retrieved from the data store 123. For example, the predictions may include predictions as to which data features within the HR data 112 of the employees are most influential on the pay disparity (pay equity scores, etc.). The predictive analytics 124 may include machine learning tools for supervised learning such as classification, regression, etc., and/or unsupervised learning tools such as clustering, etc. The parity detection module 121 may also include the logic for detecting, explaining, correcting and preventing pay disparity described according to various embodiments, which may be output or otherwise provided to other components of the host platform 120.

A cloud services 125 component may facilitate requests and response (e.g., HTTP, HTML, etc.) with client devices displaying one or more user interfaces 130 and 132 associated with the pay disparity and recommendation software. The cloud services 125 may support multiple tenants such that one or more tenants can communicate with the parity detection module 121. For example, each company on the platform may be a different tenant. As another example, different users within a same company may be different tenants (e.g., each department in a company may have their own access to data, etc.). In this example, the user interfaces may include a mobile UI 130 and desktop UI 132. For example, the desktop UI 132 may provide a window or dashboard that allows administrator users the ability to customize the parity application and to build and test predictive models. The desktop UI 132 may also be used by HR users to view analytical results and to make business decisions using available analytics tools. In some embodiments, the mobile UI 130 may provide the same functions as the desktop UI 132. As another example, the mobile UI 130 may provide HR users with the ability to receive alerts generated from analytical results, and to conduct a subset of business operations on the go. Both the mobile UI 130 and the desktop UI 132 may be displayed on user devices such as mobile phones, laptops, desktops, servers, workstations, tablets, and the like.

According to various embodiments, the pay equity disparity and recommendation system may perform various steps to help reduce disparity of pay among users in an organization. For example, the system may assess the situation by exploring historical organization data and searching for different factors. The system may create a pay equity definition by assigning pay equity indices/scores to each of the employees company-wide. This provides a normalization value that can be used to compare employees who perform different tasks, in different locations, with different experience, tenure, etc. The system may use machine learning to predict or otherwise discover what data drives the pay equity indices such as staring salary, manager churn, maternity leave, etc. Next, the system may review the influencers, identify users who are affected, and provide suggested courses of action to take to improve both the pay disparity of a user and the company as a whole. These suggestions may be output via a user interface where a reviewer may configure or make changes to payment data which can be simulated to see how the changes will effect the pay equity indices.

Also, the pay equity disparity and recommendation system may perform a parity analysis for a single user (e.g., a single employee) to analyze and explain the individual's parity score. This can provide a level of personalization for a particular user, in addition to performing the parity scoring for a group of users.

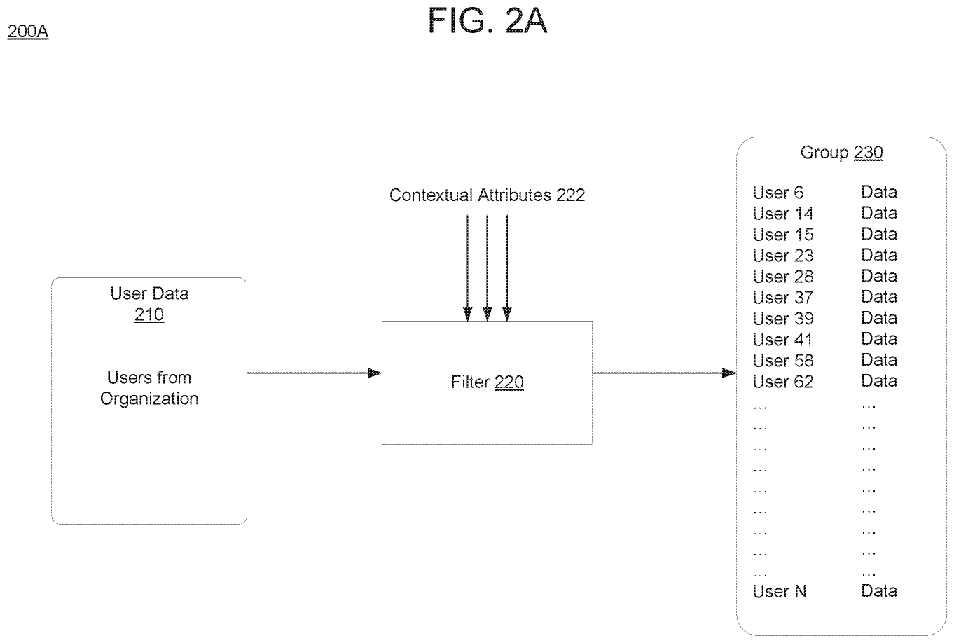

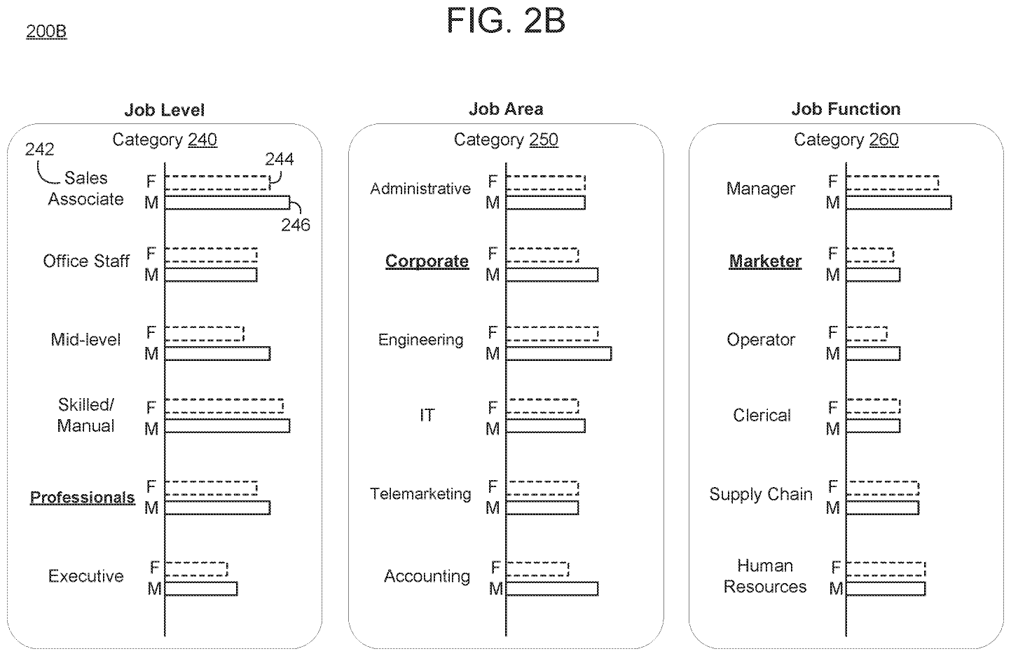

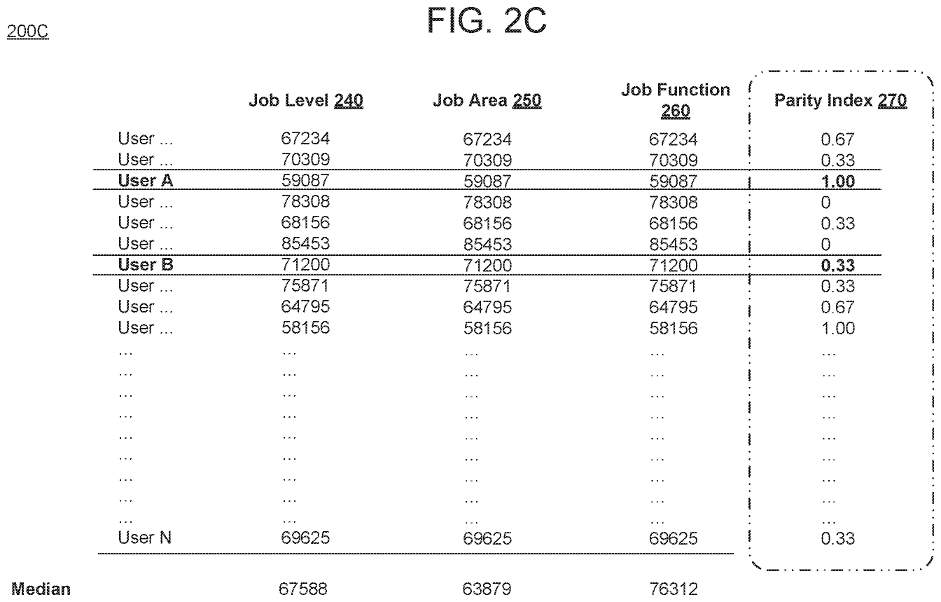

FIG. 2A illustrates a process 200A of grouping users based on contextual attributes in accordance with an example embodiment. To generate accurate pay equity results, the system may group users of an organization into subsets. In other words, various contextual attributes 222 may be used to identify a subset of users 230 from user data 210 which includes data of all users in the organization. The contextual attributes 222 may include control attributes that are indirectly related to calculating pay equity. Examples of the contextual attributes 222 include geographical location (e.g., by city, by state, by zip code, by country, etc.). Another example of the contextual attributes 222 is tenure (e.g., how long have you worked for the organization, how many years of experience do you have, etc.). Another example of the contextual attributes 222 is performance evaluation data. For example, employees with poor performance ratings or average performance ratings cannot be expected to have the same pay as employees in the same area who have outstanding performance ratings. Other examples of contextual attributes are possible and may be dynamically configured by an administrator user, etc.

FIG. 2B illustrates a user interface that provides evidence that there is possible parity issues for a plurality of job-related categories 240, 250, and 260 of a group of users in accordance with an example embodiment, and FIG. 2C illustrates a display 200C which includes user values per category and a parity index associated with the user values in accordance with an example embodiment. Here, the categories 240, 250, and 260 may be determined in advance or by an administrator. Each of the categories 240-260 may include a different subset of users, although there may be some overlapping users in each subset since the categories are not mutually exclusive (i.e., a user can be impacted in multiple categories). For example, a given user may be affected by different categories. FIG. 2B illustrates a basic example of the attributes (e.g., attribute 242, etc.) that may be included in each of the categories 240-260. In this example, each user may be assigned to one of the attributes in each of the categories 240-260. The attributes may also include values 244 and 246 representing female and male values for the categories (e.g., averages). These values 244 and 246 can identify that a gender based pay disparity exists.

In the example of FIG. 2C, two users (users A and B) have the same values for the categories 240, 250, and 260 shown in FIG. 2B. In particular, both users A and B are professionals working in the marketing department of a corporation. Furthermore, the two users A and B have been previously grouped together based on contextual attributes 222 such as geographic location, tenure, and performance. As shown in FIG. 2C, each of the salaries of the different users can be compared with other users who are assigned to the same attribute in the category. In this example, users assigned to the professional attribute in category 240 have a median salary of $67,588. Meanwhile, users assigned to the corporate job area in category 250 have a median salary of $63,879. Furthermore, users assigned to the marketer job function in category 260 have a median salary of $76,312. Here, the median salaries of each of the categories differs because there are different subsets of users in each category. It should be appreciated that some of the user may overlap, etc. Accordingly, a user may be impacted by multiple categories.

There are different ways to determine the PEI of a user based on various compensation attributes such as median salary, maximum salary, minimum salary, etc. However, in this example, a user is either given a score of 1 or 0 depending on whether the user has a salary below the median for a category or above a median for the category, respectively. Then, the scores are aggregated across the categories and divided by the number of categories. In FIG. 2C, user A has a salary of $59,087, which is below the median salary in all three categories. Therefore, user A is given a score of 3 out of 3 (3/3)=1.00. Meanwhile, user B has a salary of $71,200 which is above the median in two categories 240 and 250, and below the median in the third category 260. Therefore, user B is given a score of 1 out of 3 (1/3)=0.33.

As further noted above, these pay equity indexes (PEIs) can be converted into pay equity scores (PESs) by flipping the ratio into a percentage. For example, a PEI of 1.00 may be converted into a score of 0 while the PEI of 0.33 may be converted into a PES of 67. These scores may be output to a compensation advisor, etc. of the organization via a dashboard. In addition, the scores (or the raw PEIs) may be operated on by applications, predictive analytics, statistics, etc. to generate further insights into the data.

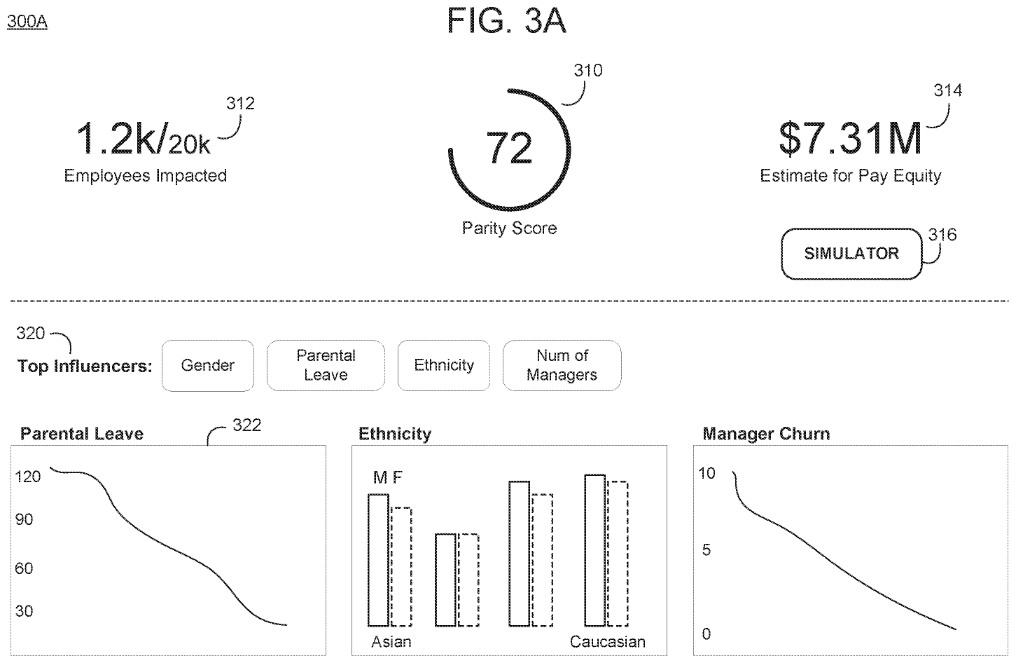

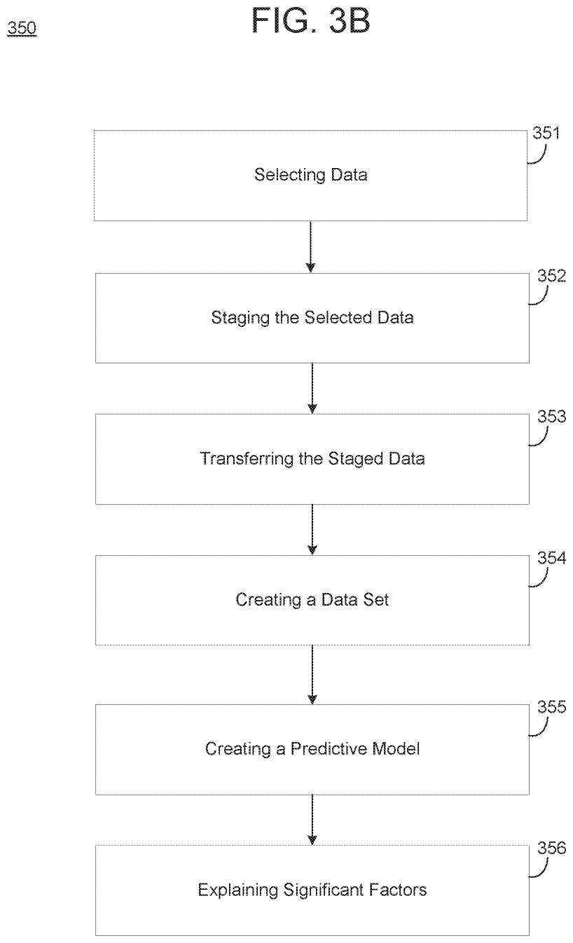

FIG. 3A illustrates a user interface 300 displaying parity information of an organization in accordance with an example embodiment. Referring to FIG. 3A, the user interface 300 may display an aggregate pay equity score 310 for an organization as a whole, a value 312 representing the total number of employees at the organization that are affected by pay equity (e.g., employees who have poor pay equity scores, etc.), and a value 314 representing a cost to fix the disparity in pay equity.

In this example, detecting pay disparity may use the PEI to quantify pay disparity in terms of the number of employee impacted, the estimated cost, and the overall pay equity score (or index) for a given employee population. By default, the number of impacted employees is defined as a count of all employees having a PEI of greater than 0, or of all employees having a PES of less than 100. By default, the estimated cost associated with pay disparity may refer to the sum of all employee pay disparity (or Salary Median−Salary Employee), for impacted employees (or Salary Median>Salary Employee). By default, aggregated PES (or PES Aggr) may be defined as the sum of employee PES (or PES Employee) divided by the total number of employees. Similarly, aggregated PEI (or PEI Aggr) may be defined as the sum of employee PEI (PEI Employee) divided by the total number of employees.

Explaining pay disparity may include describing the root causes in terms of significant factors, such as hours of absence, manager churn (number of mangers in a given period of time), ethnicity, starting salary ratio, etc. These factors are selected automatically from a set of input attributes in the historical data of the company. For example, machine learning algorithms such as classification and regression may be used to associate or correlate a set of independent variables with the target variable in the historical data. In this case, PEI (or Pay Equity Index) is the target variable for which its value is what the algorithm is trying to predict with respect to the independent variables. The independent variables may include employee attributes acting as potential predictors, which include demographics (age, gender, disability, ethnicity, etc.), employment (job category, employee class, employment level, grade, etc.), development (key position, performance rating, potential rating, etc.) succession (critical job role, succession rating, successor readiness, etc.), tenure (grade tenure, organization tenure, position tenure, time in grade, etc.), compensation (salary, stock options, etc.), and the like.

FIG. 3B illustrates a process 350 for creating an explanation of pay disparity in accordance with example embodiments. The process 350 may include (1) selecting data, (2) staging the data, (3) transferring the data, (4) creating a data set, (5) creating a model, and (6) explaining the results and providing actions to take.

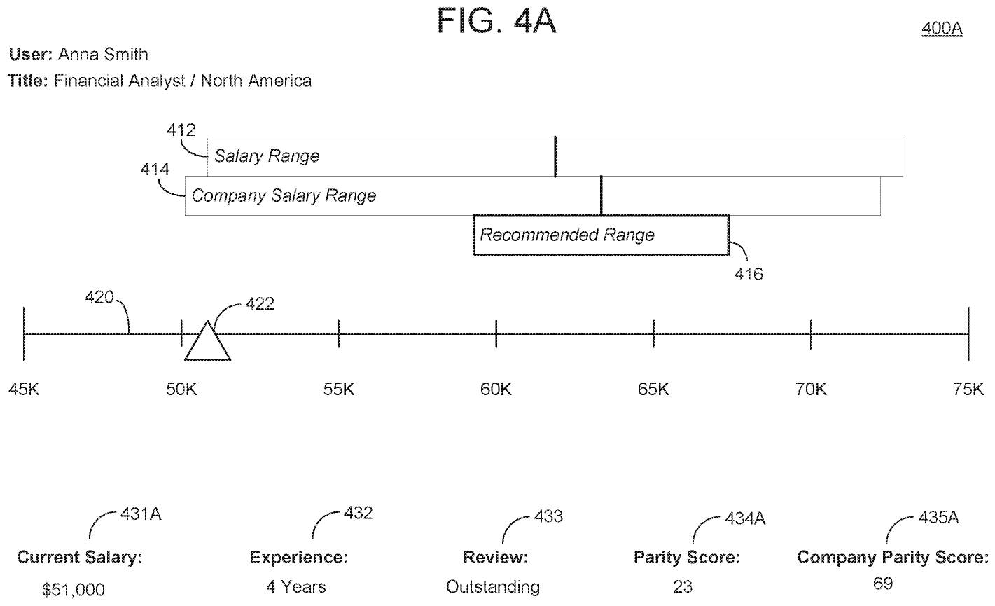

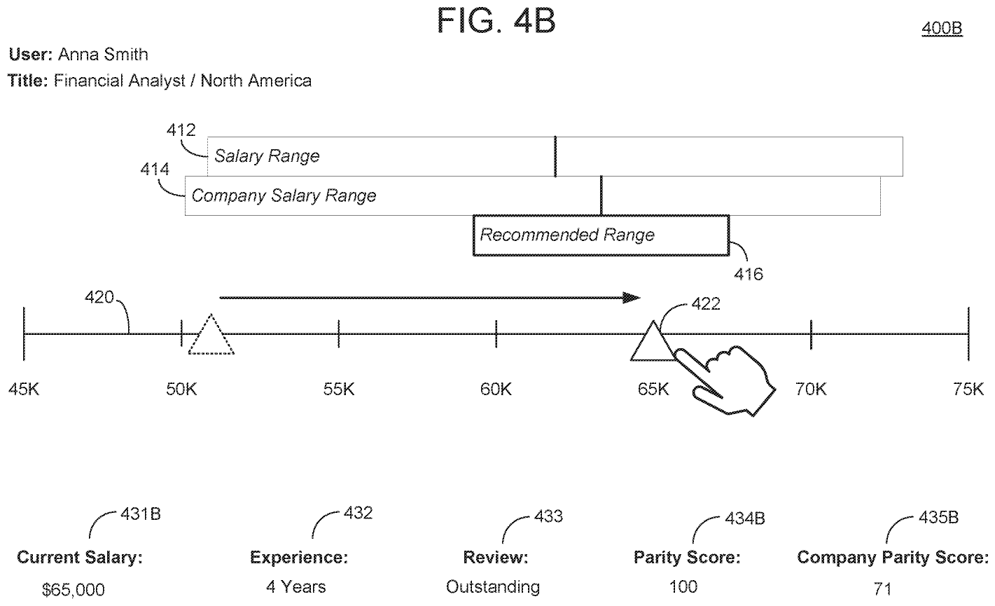

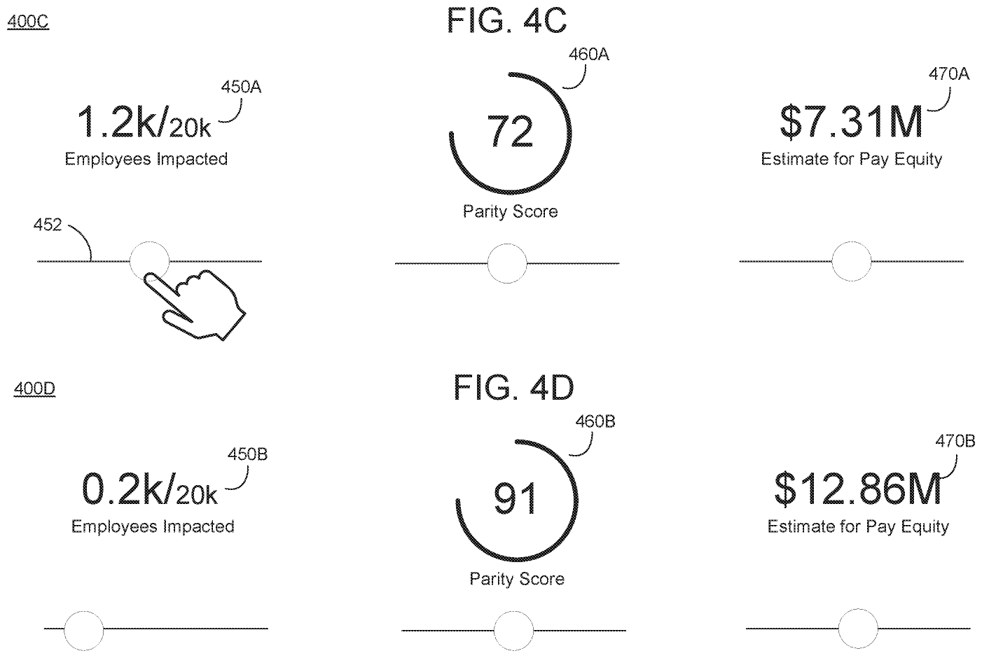

Predictive analytics may determine that factors such as gender, parental leave, ethnicity, and number of managers result in the causes of pay disparity among men and women. As another example, parity may be discovered among other categories of persons including different generations (ages), different ethnicities, etc. The results may be output as key influencers 320 (shown in FIG. 3A) of the parity values. The HR data retrieved from the organizations data may be used to create an explanation such as charts, graphs, descriptions, etc., which provide the viewer with information and understanding as to why pay disparity exists, where it exists, and suggested courses of action for fixing the pay disparity (described in the examples of FIGS. 4A and 4B).

Referring to FIG. 3B, the selected data may be extracted from the HR data of the organization, in 351. The selected data may be staged so that it can be transferred to an analytical processing system, in 352. The staged data may then be transferred, in 353. The transferred data may be pre-processed in 354 into an analytical data set that is capable of being input into a machine learning model. The process may include specifying data storage type, data value type, as well as creating categorical, ordinal, aggregation and target attributes. In 355, the analytical data set may be used to generate an explanatory model for predicting the target variable, such as PEI. The model may be a predictive/machine learning model that may be used here to create associations between the independent variables and the target variable and help identify the key influencers of the pay equity indexes. The final step in 356 is to extract significant factors from an explanatory model, and to demonstrate such an effect from historical data.

The predictive analytics may analyze the data used to create the pay equity indices for the group of users to identify patterns that exist within the data. The patterns may be data fields/attributes that drive the pay equity indices from going up or down. In other words, the attributes which influence the pay equity indices the most. In the example of FIG. 3A, the top influencers are shown as charts 322. This provides the viewer with a visual understanding of the effect of the attribute on pay disparity.

Furthermore, the user interface 300 also includes a simulator button 316. When pressed by the user, the simulator button 316 may open up a user interface which provides additional information fields that can be used to modify/configure different payment data for the group of users. Furthermore, before effecting these changes, the system can be used to simulate such changes to see how they effect the pay equity index of an individual user and of the organization as a whole.

FIGS. 4A-4D are diagrams illustrating a simulation interface for simulating a change in parity information based on user inputs in accordance with an example embodiment. Referring to FIG. 4A, a user interface 400A shows the current salary and other information for a user named Anna Smith. The user's attributes 431, 432, and 433 are shown and include current salary, experience, and performance information, respectively. Here, the system has determined that a pay equity score 434 for Anna Smith is 23 and a pay equity score 435 for the company as a whole is 69. In addition, salary ranges 412 and 414 are graphed along an axis 420 to show the different ranges, where the axis includes values for salary.

To help the viewer make changes, the system may predict one or more changes to make such as a recommended salary range 416 and display it in relation to the market salary range 412 and the company salary range 414. In this example, the axis 420 includes a slider 422 that allows a user to adjust the compensation value for Anna Smith, and simulate such changes. Here, the user may use an input mechanism (e.g., finger, mouse, pointer device, etc.) to move slider 422 along the axis 420, as shown in the example of FIG. 4B. Here, the user interface has changed from 400A to 400B in which values for current salary 431, parity score 434, and company parity score 435 have changed as a result of the proposed change in salary for Anna Smith. These changes are simulated changes that enable the viewer to see how changes influence the pay equity for both the user and the company.

FIGS. 4C and 4D illustrate a different simulation example. Here, a user interface 400C includes a similar interface as shown in FIG. 3A. In particular, the user interface 400C includes a value 450 for employees impacted by pay disparity, value 460 for parity score (pay equity score), and a value 470 for cost estimate to fix the pay disparity. Each of the different values 450, 460, and 470 may be configured/modified by a user and then simulated. For example, a slider 452 may be moved by the user to change an amount of one or more of the three values 450, 460, and 470. In FIG. 4C, the user changes the value 450 for employees impacted from 1,200 to 200 as shown in FIG. 4D. In response, the system may simulate changes to the parity score 460 and the cost estimate 470. For example, one of the metrics 450A, 460A, and 470A may be changed at a time, and the system may imply a change or possible change to the other two metrics as a simulated response.

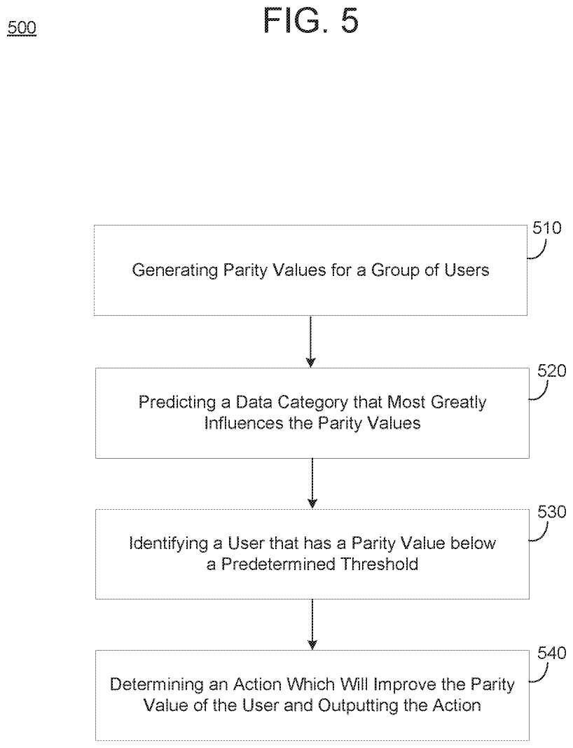

FIG. 5 illustrates a method 500 a method of detecting parity values and making a recommendation based thereon, in accordance with an example embodiment. For example, the method 500 may be performed by a service, an application, or other program that is executing on a host platform such as a database node, a cloud, a web server, an on-premises server, another type of computing system, or a combination of devices/nodes.

Referring to FIG. 5, in 510, the method may include generating parity values for a group of users, where each parity value comprises an indicator of inequity for a value of a respective user with respect to corresponding values of other users in the group. For example, each parity value may represent whether a user's compensation is fair, and a degree of parity with respect to other users. In some embodiments, the parity values may be based on a plurality of different attributes such as gender, age, generation, job function, performance, salary, and the like. In other words, the parity value is not just a compensation value but rather takes into account a fuller picture of the user. Furthermore, prior to generating the parity values, users may be grouped, segregated, filtered, etc. based on contextual attributes. For example, users that share one or more of age, experience, geographic location, function, title, and the like, may be grouped together and analyzed. In some embodiments, the generating may further include normalizing the parity values for the group of users based on values of each of the users with respect to a plurality of different attributes.

In 520, the method may include predicting at least one category of data that most greatly influences the parity values for the group of users based on one or more machine learning models. Different categories of historical data related to the job/employment may be analyzed. The historical data may be human resources data that includes compensation information, benefits, salary, stock, and other equity given to employees. In addition, the historical data may include information about management, starting salary, time of leave, career level, and the like. The machine learning models may identify influences that drive the parity values from among the different historical data. The machine learning models may identify patterns in the data which correlate to parity values going up or down. Likewise, the machine learning models may predict which influencers most greatly impact each user's parity value. In some embodiments, the predicting the at least one category may include predicting at least one root cause of parity for the group of users based on human resources data of a company. For example, the root cause may be the most significant factor that contributes in the parity and may include manager turnover, geographic location, ethnicity, or the like.

In 530, the method may include identifying a user that has a parity value below a predetermined threshold. Further, in 540, the method may include determining an action which will improve the parity value of the identified user based on the at least one predicted influential category, and outputting a recommendation which includes the action. In some embodiments, the method may further include outputting a user interface to a display screen, wherein the user interface comprises a user input field for simulating changes in a value of at least one influential category of data. In some embodiments, the method may further include receiving, via the user input field, a new value for the at least one influential category of data, and regenerating the parity value for the user based on the new value.

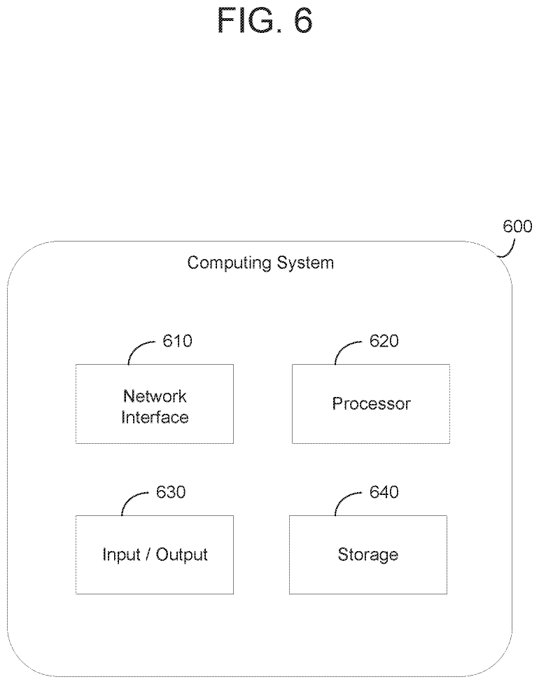

FIG. 6 illustrates a computing system 600 that may be used in any of the methods and processes described herein, in accordance with an example embodiment. For example, the computing system 600 may be a database node, a server, a cloud platform, a user device, or the like. In some embodiments, the computing system 600 may be distributed across multiple computing devices such as multiple database nodes. Referring to FIG. 6, the computing system 600 includes a network interface 610, a processor 620, an input/output 630, and a storage device 640 such as an in-memory storage, and the like. Although not shown in FIG. 6, the computing system 600 may also include or be electronically connected to other components such as a display, an input unit(s), a receiver, a transmitter, a persistent disk, and the like. The processor 620 may control the other components of the computing system 600.

The network interface 610 may transmit and receive data over a network such as the Internet, a private network, a public network, an enterprise network, and the like. The network interface 610 may be a wireless interface, a wired interface, or a combination thereof. The processor 620 may include one or more processing devices each including one or more processing cores. In some examples, the processor 620 is a multicore processor or a plurality of multicore processors. Also, the processor 620 may be fixed or it may be reconfigurable. The input/output 630 may include an interface, a port, a cable, a bus, a board, a wire, and the like, for inputting and outputting data to and from the computing system 600. For example, data may be output to an embedded display of the computing system 600, an externally connected display, a display connected to the cloud, another device, and the like. The network interface 610, the input/output 630, the storage 640, or a combination thereof, may interact with applications executing on other devices.

The storage device 640 is not limited to a particular storage device and may include any known memory device such as RAM, ROM, hard disk, and the like, and may or may not be included within a database system, a cloud environment, a web server, or the like. The storage 640 may store software modules or other instructions which can be executed by the processor 620 to perform the method shown in FIG. 5. According to various embodiments, the storage 640 may include a data store having a plurality of tables, partitions and sub-partitions. Here, the data store may store parity data in columnar fashion. Therefore, the storage 640 may be used to store database objects, records, items, entries, and the like, associated with pay equity.

According to various embodiments, the processor 620 may generate parity values for a group of users, where each parity value comprises an indicator of inequity for a value of a respective user with respect to corresponding values of other users in the group. Here, the parity values may be derived from a number of different attributes related to employment such as age, gender, experience, location, and the like. The processor 620 may further analyze historical data associated with an organization and predict at least one category of the user data that most greatly influences the parity values for the group of users based on one or more machine learning models. For example, parity may be influenced by factors such as the number of managers that a user has had, the starting salary of the user, user performance, and the like.

The processor 620 may further identify a user that has a parity value below a predetermined threshold (e.g., a group of users, etc.), and determine an action which will improve the parity value of the identified user based on the at least one predicted influential category, and output a recommendation which includes the action. The recommended action may be provided to improve the overall parity score of the organization as a whole.

As will be appreciated based on the foregoing specification, the above-described examples of the disclosure may be implemented using computer programming or engineering techniques including computer software, firmware, hardware or any combination or subset thereof. Any such resulting program, having computer-readable code, may be embodied or provided within one or more non-transitory computer-readable media, thereby making a computer program product, i.e., an article of manufacture, according to the discussed examples of the disclosure. For example, the non-transitory computer-readable media may be, but is not limited to, a fixed drive, diskette, optical disk, magnetic tape, flash memory, external drive, semiconductor memory such as read-only memory (ROM), random-access memory (RAM), and/or any other non-transitory transmitting and/or receiving medium such as the Internet, cloud storage, the Internet of Things (IoT), or other communication network or link. The article of manufacture containing the computer code may be made and/or used by executing the code directly from one medium, by copying the code from one medium to another medium, or by transmitting the code over a network.

The computer programs (also referred to as programs, software, software applications, “apps”, or code) may include machine instructions for a programmable processor, and may be implemented in a high-level procedural and/or object-oriented programming language, and/or in assembly/machine language. As used herein, the terms “machine-readable medium” and “computer-readable medium” refer to any computer program product, apparatus, cloud storage, internet of things, and/or device (e.g., magnetic discs, optical disks, memory, programmable logic devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal that may be used to provide machine instructions and/or any other kind of data to a programmable processor.

The above descriptions and illustrations of processes herein should not be considered to imply a fixed order for performing the process steps. Rather, the process steps may be performed in any order that is practicable, including simultaneous performance of at least some steps. Although the disclosure has been described in connection with specific examples, it should be understood that various changes, substitutions, and alterations apparent to those skilled in the art can be made to the disclosed embodiments without departing from the spirit and scope of the disclosure as set forth in the appended claims.

What is claimed is:

1. A computing system comprising:
a storage configured to store user data; and
a processor configured to
generate parity values for a group of users, where each parity value comprises an indicator of inequity for a value of a respective user with respect to corresponding values of other users in the group,
predict at least one category of the user data that most greatly influences the parity values for the group of users based on one or more machine learning models,
identify a user that has a parity value below a predetermined threshold, and
determine an action which will improve the parity value of the identified user based on the at least one predicted influential category, and output a recommendation which includes the action.

2. The computing system of claim 1, wherein the processor is further configured to normalize the parity values for the group of users based on values of each of the users with respect to a plurality of different attributes.

3. The computing system of claim 1, wherein the processor is further configured to segregate the group of users from a larger set of users based on shared contextual attributes among the group of users.

4. The computing system of claim 1, wherein each parity value is generated based on whether the respective user is a man or a woman.

5. The computing system of claim 1, wherein the processor is further configured to output a user interface to a display screen, wherein the user interface comprises a user input field for simulating changes to a value of at least one influential category of data.

6. The computing system of claim 5, wherein the processor is further configured to receive, via the user input field, a new value for the at least one influential category of data, and regenerate the parity value for the user based on the new value.

7. The computing system of claim 1, wherein the processor is configured to predict at least one root cause of parity for the group of users based on human resources data of a company.

8. The computing system of claim 7, wherein the processor is further configured to extract the human resources data from a database.

9. A method comprising:
generating parity values for a group of users, where each parity value comprises an indicator of inequity for a value of a respective user with respect to corresponding values of other users in the group;
predicting at least one category of data that most greatly influences the parity values for the group of users based on one or more machine learning models;
identifying a user that has a parity value below a predetermined threshold; and
determining an action which will improve the parity value of the identified user based on the at least one predicted influential category, and outputting a recommendation which includes the action.

10. The method of claim 9, wherein the generating further comprises normalizing the parity values for the group of users based on values of each of the users with respect to a plurality of different attributes.

11. The method of claim 9, further comprising segregating the group of users from a larger set of users based on shared contextual attributes among the group of users.

12. The method of claim 9, wherein each parity value is generated based on whether the respective user is a man or a woman.

13. The method of claim 9, further comprising outputting a user interface to a display screen, wherein the user interface comprises a user input field for simulating changes in a value of at least one influential category of data.

14. The method of claim 13, further comprising receiving, via the user input field, a new value for the at least one influential category of data, and regenerating the parity value for the user based on the new value.

15. The method of claim 1, wherein the predicting the at least one category comprises predicting at least one root cause of parity for the group of users based on human resources data of a company.

16. The method of claim 15, wherein the method further comprises extracting the human resources data from a database.

17. A non-transitory computer-readable medium storing instructions which when executed by a processor cause a computer to perform a method comprising:
generating parity values for a group of users, where each parity value comprises an indicator of inequity for a value of a respective user with respect to corresponding values of other users in the group;
predicting at least one category of data that most greatly influences the parity values for the group of users based on one or more machine learning models;
identifying a user that has a parity value below a predetermined threshold; and
determining an action which will improve the parity value of the identified user based on the at least one predicted influential category, and outputting a recommendation which includes the action.

18. The non-transitory computer-readable medium of claim 17, wherein the generating further comprises normalizing the parity values for the group of users based on values of each of the users with respect to a plurality of different attributes.

19. The non-transitory computer-readable medium of claim 17, wherein the method further comprises segregating the group of users from a larger set of users based on shared contextual attributes among the group of users.

20. The non-transitory computer-readable medium of claim 17, wherein each parity value is generated based on whether the respective user is a man or a woman.
